(19) United States
(12) Patent Application Publication
(10) Pub. No.: US 2025/0201775 A1
(43) Pub. Date: Jun. 19, 2025

(54) HIGH CAPACITANCE HYBRID BONDED CAPACITOR DEVICE

(71) Applicant: International Business Machines Corporation, Armonk, NY (US)

(72) Inventors: Nicholas Alexander Polomoff, Hopewell Junction, NY (US); Mukta Ghate Farooq, Hopewell Junction, NY (US); Kishan Jayanand, Cohoes, NY (US); Nicholas Latham, Albany, NY (US); Huai Huang, Clifton Park, NY (US); Ravi K. Bonam, Albany, NY (US)

(21) Appl. No.: 18/544,114

(22) Filed: Dec. 18, 2023

(51) Int. Cl. H01L 25/065; H01L 23/00; H01L 25/00

(52) U.S. Cl. CPC H01L 25/0657; H01L 24/05; H01L 24/06; H01L 24/08; H01L 24/80; H01L 25/50; H10D 1/696; H01L 2224/0346; H01L 2224/03466; H01L 2224/03845; H01L 2224/05026; H01L 2224/05147; H01L 2224/05149; H01L 2224/05157; H01L 2224/05166; H01L 2224/05181; H01L 2224/05184; H01L 2224/05186; H01L 2224/05571; H01L 2224/05624; H01L 2224/05647; H01L 2224/05657; H01L 2224/05676; H01L 2224/05684; H01L 2224/0603; H01L 2224/08145; H01L 2224/80357; H01L 2224/80379; H01L 2224/80896; H01L 2225/06531; H01L 2225/06565; H01L 2924/0132; H01L 2924/04941; H01L 2924/04953; H01L 2924/0533; H01L 2924/0534; H01L 2924/05342; H01L 2924/0535; H01L 2924/05432; H01L 2924/0545; H01L 2924/0549; H01L 2924/059

(57) ABSTRACT

Techniques are provided for hybrid bonding metallic bonding pads embedded in high-K dielectric material to form a high capacitance device. For example, a device comprises a first semiconductor structure bonded to a second semiconductor structure, and a plurality of metal pads at an interface portion between the first semiconductor structure and the second semiconductor structure. The plurality of metal pads are disposed in a high-K dielectric layer. The plurality of metal pads and the high-K dielectric layer comprise at least one capacitor.

### BACKGROUND

Innovations in semiconductor fabrication and packaging technologies have enabled the development of smaller scale, higher density semiconductor integrated circuit (IC) chips, as well as the development of highly integrated chip modules with wiring and area array input/output (I/O) contact densities that enable dense packaging of IC chips. For certain applications, high-performance electronic devices are constructed by fabricating semiconductor devices on separate wafers and bonding the wafers together to construct an integrated semiconductor device package.

Various conventional techniques, such as two-dimensional (2-D) packaging and three-dimensional (3-D) packaging techniques, can be utilized to construct a semiconductor device package structure. With 2-D packaging, package structures can be constructed by connecting multiple semiconductor IC dies directly to a package substrate using direct chip attachment (DCA) techniques (e.g., flip-chip bonding), wherein the semiconductor IC chips are mounted in the package laterally adjacent to each other (e.g., in a single plane, or coplanar to each other). In this regard, 2-D packaging techniques can require a relatively large package footprint to accommodate multiple semiconductor IC chips. In addition, the I/O communication paths between adjacent chips can be very long since chip-to-chip I/O communication is made through chip-substrate-chip connections and interfaces, which can result in noisy and long interconnect lengths, which can degrade signal integrity.

On the other hand, with 3-D packaging, two more semiconductor IC chips are vertically stacked on top of each other, and interconnected (without an intermediate layer or package substrate) using vertical interconnection structures such as through silicon via (TSV) interconnect structures. While 3-D packaging can provide improvement in communication bandwidth between the stacked chips, there are various problematic issues associated with 3-D packaging.

For example, some issues associated with current 3-D packaging approaches include, but are not limited to: (i) low capacitance structures; (ii) increased noise from power supplies at high frequency due to high speed circuit switching; (iii) decreased stack assembly yield, requiring more chip real estate for yield loss mitigation through, for example, redundancy; (iv) requirements for extra chip processing such as backside thinning to keep the stacked chips as thin as possible as well as extra fabrication specific steps for TSVs, (v) a chip stacking limits, etc.

### SUMMARY

Embodiments of the disclosure include hybrid bonding structures and techniques for hybrid bonding metallic bonding pads embedded in high-K dielectric material to form a high capacitance device.

In one embodiment, a semiconductor device includes a first semiconductor structure bonded to a second semiconductor structure; and a plurality of metal pads at an interface portion between the first semiconductor structure and the second semiconductor structure. The plurality of metal pads are disposed in a high-K dielectric layer. The plurality of metal pads and the high-K dielectric layer include at least one capacitor.

As may be combined with the preceding paragraph, the first semiconductor structure may be hybrid bonded to the second semiconductor structure. The first semiconductor structure may include a first metal layer connected to at least a first voltage source. A first subset of the plurality of metal pads may be connected to the first metal layer, and a second subset of the plurality of metal pads may be electrically isolated from the first metal layer.

As may be combined with the preceding paragraphs, the second semiconductor structure may include a second metal layer connected to at least a second voltage source. The first subset of the plurality of metal pads may be electrically isolated from the second metal layer, and the second subset of the plurality of metal pads may be connected to the second metal layer. Respective ones of metal pads in the first subset of the plurality of metal pads may be disposed in an alternating configuration with respective ones of metal pads in the second subset of the plurality of metal pads.

As may be combined with the preceding paragraphs, the first semiconductor structure may include a first metal layer connected to at least a first voltage source, and the second semiconductor structure may include a second metal layer connected to at least a second voltage source. At least some of the plurality of metal pads may be floating with respect to one of the first metal layer and the second metal layer.

As may be combined with the preceding paragraphs, the high-K dielectric layer may include at least two high-K dielectric materials that are different from each other. A second plurality of metal pads may be disposed at a second interface portion between the first semiconductor structure and the second semiconductor structure, wherein the second plurality of metal pads are disposed in a second high-K dielectric layer. The second plurality of metal pads and the second high-K dielectric layer may include at least one other capacitor. The at least one capacitor and the at least one other capacitor may be connected to each other in parallel or in series.

As may be combined with the preceding paragraphs, a second plurality of metal pads may be disposed at a second interface portion between the first semiconductor structure and the second semiconductor structure, wherein the second plurality of metal pads are disposed in a low-K dielectric layer, and the second plurality of metal pads include signal lines.

Advantageously, a high capacitance structure is formed through hybrid bonding. The illustrative embodiments allow for the creation of a capacitor structure with different materials that produces increased yields and permits pre-charging to limit in-rush currents at power-up of high voltage direct current (HVDC) circuits. The illustrative embodiments further provide for decreased noise from a power supply at high frequency bands due to circuit switching at high speeds. Moreover, the embodiments allow for high-density integration without the disadvantages associated with conventional 3-D packaging techniques as discussed above.

In another embodiment, a semiconductor device includes a first semiconductor die including a first plurality of metal pads disposed in a first high-K dielectric layer, and a second semiconductor die including a second plurality of metal pads disposed in a second high-K dielectric layer. The first semiconductor die is bonded to the second semiconductor die. Respective ones of the first plurality of metal pads are aligned with respective ones of the second plurality of metal pads. The first and second plurality of metal pads and the first and second high-K dielectric layers form at least one capacitor.

As may be combined with the preceding paragraphs, a material of the first high-K dielectric layer may be different from a material of the second high-K dielectric layer. A subset of the plurality of first metal pads may be floating with respect to a voltage source of the first semiconductor die, and a subset of the plurality of second metal pads may be floating with respect to a voltage source of the second semiconductor die.

In another embodiment, an apparatus includes two or more semiconductor dies hybrid bonded together, and a plurality of metal structures at an interface portion between a first semiconductor die of the two or more semiconductor dies and a second semiconductor die of the two or more semiconductor dies. The plurality of metal structures are disposed in at least one high-K dielectric layer, wherein the plurality of metal structures and the at least one high-K dielectric layer include at least one capacitor.

As may be combined with the preceding paragraphs, the first semiconductor die may include a first metal layer connected to at least a first voltage source. A first subset of the plurality of metal structures may be connected to the first metal layer, and a second subset of the plurality of metal structures may be electrically isolated from the first metal layer. The second semiconductor die may include a second metal layer connected to at least a second voltage source. The first subset of the plurality of metal structures may be electrically isolated from the second metal layer, and the second subset of the plurality of metal structures may be connected to the second metal layer. Respective ones of metal structures in the first subset of the plurality of metal structures may be disposed in an alternating configuration with respective ones of metal structures in the second subset of the plurality of metal structures.

As may be combined with the preceding paragraphs, the at least one high-K dielectric layer may include at least a first high-K dielectric layer including a first high-K dielectric material and a second high-K dielectric layer including a second high-k dielectric material different from the first high-K dielectric material.

In another embodiment, an apparatus includes a first semiconductor structure disposed on top of and facing a second semiconductor structure, wherein the first semiconductor structure and the second semiconductor structure are bonded to each other. A plurality of metal structures span an interface portion between the first semiconductor structure and the second semiconductor structure, wherein the plurality of metal structures are disposed in at least one high-K dielectric layer, and the plurality of metal structures and the at least one high-K dielectric layer include at least one capacitor.

As may be combined with the preceding paragraphs, a second plurality of metal structures may span a second interface portion between the first semiconductor structure and the second semiconductor structure. The second plurality of metal structures may be disposed in at least one second high-K dielectric layer, wherein the second plurality of metal structures and the at least one second high-K dielectric layer include at least one other capacitor. The at least one capacitor and the at least one other capacitor may be connected to each other in parallel.

In another embodiment, a method includes forming a first semiconductor structure on a first semiconductor substrate, wherein the first semiconductor structure includes a first plurality of metal pads disposed in a first high-K dielectric layer, and forming a second semiconductor structure on a second semiconductor substrate, wherein the second semiconductor structure includes a second plurality of metal pads disposed in a second high-K dielectric layer. Respective ones of the first plurality of metal pads are aligned with respective ones of the second plurality of metal pads. A thermal treatment process is performed to bond the first semiconductor structure to the second semiconductor structure, wherein the thermal treatment process integrates the first plurality of metal pads with the second plurality of metal pads to create a plurality of metal structures spanning an interface between the first semiconductor structure to the second semiconductor structure. The plurality of metal structures and the first and second high-K dielectric layers form at least one capacitor.

As may be combined with the preceding paragraphs, a material of the first high-K dielectric layer may be different from a material of the second high-K dielectric layer. The thermal treatment process may anneal the first plurality of metal pads and the second plurality of metal pads.

These and other features and advantages of embodiments described herein will become more apparent from the accompanying drawings and the following detailed description.

### BRIEF DESCRIPTION OF THE DRAWINGS

FIGS. 1A and 1B depict cross-sectional views of first and second semiconductor structures each including a photoresist on hybrid bonding level dielectric layers and underlying metal levels, according to an embodiment of the invention.

FIGS. 2A and 2B depict cross-sectional views of the first and second semiconductor structures following photoresist patterning and removal of portions of the hybrid bonding level dielectric layers to form openings for a high-K dielectric capacitor region, according to an embodiment of the invention.

FIGS. 3A and 3B depict cross-sectional views of the first and second semiconductor structures following photoresist removal and deposition of high-K dielectric material, according to an embodiment of the invention.

FIGS. 4A and 4B depict cross-sectional views of the first and second semiconductor structures following planarization of the high-K dielectric material and deposition and patterning of another photoresist, according to an embodiment of the invention.

FIGS. 5A and 5B depict cross-sectional views of the first and second semiconductor structures following etching of exposed portions of the high-K dielectric layer and a hybrid bonding dielectric layer, according to an embodiment of the invention.

FIGS. 6A and 6B depict cross-sectional views of the first and second semiconductor structures following photoresist removal and deposition and patterning of another photoresist, according to an embodiment of the invention.

FIGS. 7A and 7B depict cross-sectional views of the first and second semiconductor structures following etching of exposed portions of the high-K dielectric layer and a hybrid bonding dielectric layer from the first and second semiconductor structures, according to an embodiment of the invention.

FIGS. 8A and 8B depict cross-sectional views of the first and second semiconductor structures following photoresist removal, deposition of a liner layer and deposition of a metal fill layer, according to an embodiment of the invention.

FIG. 9 depicts a cross-sectional view of the first and second semiconductor structures following planarization of the liner and metal fill layers, flipping of the first semiconductor structure onto the second semiconductor structure, and aligning of the first semiconductor structure with the second semiconductor structure, according to an embodiment of the invention.

FIG. 10 depicts a cross-sectional view of the first and second semiconductor structures following heat treatment and annealing, according to an embodiment of the invention.

FIG. 11 depicts a cross-sectional view of a hybrid bonding high-K dielectric capacitor region, according to an embodiment of the invention.

FIG. 12 depicts a three-dimensional view of a hybrid bonded high-K dielectric capacitor region and a hybrid bonded signal metal pad region, according to an embodiment of the invention.

FIGS. 13A and 13B depict three-dimensional views of first and second semiconductor structures each including a hybrid bonding high-K dielectric capacitor region and a hybrid bonding signal metal pad region, according to an embodiment of the invention.

FIGS. 14A and 14B respectively depict cross-sectional and three-dimensional views illustrating a hybrid bonding process of two semiconductor structures to create a single structure including a hybrid bonding high-K dielectric capacitor and hybrid bonding metal pad regions, according to an embodiment of the invention.

FIGS. 15A and 15B depict three-dimensional views illustrating a hybrid bonding process of two semiconductor structures to create a single structure including a hybrid bonding high-K dielectric capacitor and hybrid bonding metal pad regions, according to an embodiment of the invention.

FIG. 16A depicts a three-dimensional view of a hybrid bonded high-K dielectric capacitor region, according to an embodiment of the invention.

FIG. 16B depicts a three-dimensional view of high-K dielectric capacitor regions prior to hybrid bonding, according to an embodiment of the invention.

FIG. 17 depicts a cross-sectional view of two hybrid bond high-K dielectric capacitor structures connected in parallel, according to an embodiment of the invention.

FIG. 18 depicts a circuit diagram of capacitors connected in parallel, according to an embodiment of the invention.

FIG. 19A depicts a cross-sectional view of multiple hybrid bond high-K dielectric capacitor structures connected in parallel, according to an embodiment of the invention.

FIG. 19B depicts a cross-sectional view of multiple hybrid bond high-K dielectric capacitor structures connected in series, according to an embodiment of the invention.

### DETAILED DESCRIPTION

Embodiments of the disclosure will now be discussed in further detail with regard to structures and techniques for hybrid bonding metallic bonding pads embedded in high-K dielectric material to form a high capacitance device. It is to be understood that the various layers, structures, and regions shown in the accompanying drawings are schematic illustrations that are not drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, or structures, and thus, a detailed explanation of the same or similar features, elements, or structures will not be repeated for each of the drawings. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount. The term “exemplary” as used herein means “serving as an example, instance, or illustration”. Any embodiment or design described herein as “exemplary” is not to be construed as preferred or advantageous over other embodiments or designs. The word “over” as used herein to describe forming a feature (e.g., a layer) “over” a side or surface, means that the feature (e.g., the layer) may be formed “directly on” (i.e., in direct contact with) the implied side or surface, or that the feature (e.g., the layer) may be formed “indirectly on” the implied side or surface with one or more additional layers disposed between the feature (e.g., the layer) and the implied side or surface.

Further, the term “semiconductor die” or “die” as used herein refers to a block of semiconductor material on which a given functional circuit (e.g., memory circuit, processor circuitry, etc.) and metallization levels (e.g., front-end-of-line (FEOL), middle-of-line (MOL), back-end-of-line (BEOL) metallization levels) are fabricated. Similarly, a semiconductor structure may also refer to a block of semiconductor material on which a given functional circuit and metallization levels are fabricated.

To provide spatial context to the different structural orientations of the semiconductor structures shown in the drawings, XYZ Cartesian coordinates are shown in the drawings. The terms “vertical” or “vertical direction” or “vertical height” as used herein denote a Z-direction of the Cartesian coordinates shown in the drawings, and the terms “horizontal,” “horizontal direction,” “lateral,” or “lateral direction” as used herein denote an X-direction and/or a Y-direction of the Cartesian coordinates shown in the drawings.

As used herein, “high-K” refers to dielectric materials having a relative dielectric constant greater than 7.

As used herein, “low-K” refers to dielectric materials having a relative dielectric constant less than 7, and includes ultra-low-k dielectric materials.

As used herein, “hybrid bonding” refers to a 3D packing technique to connect semiconductor structures. Hybrid bonding forms connections of semiconductor structures through metal pads which are embedded in a dielectric layer at a bond interface on each semiconductor structure that is being bonded. Fusion bonding forms connections of semiconductor structures via dielectric layers at a bond interface on each semiconductor structure being bonded.

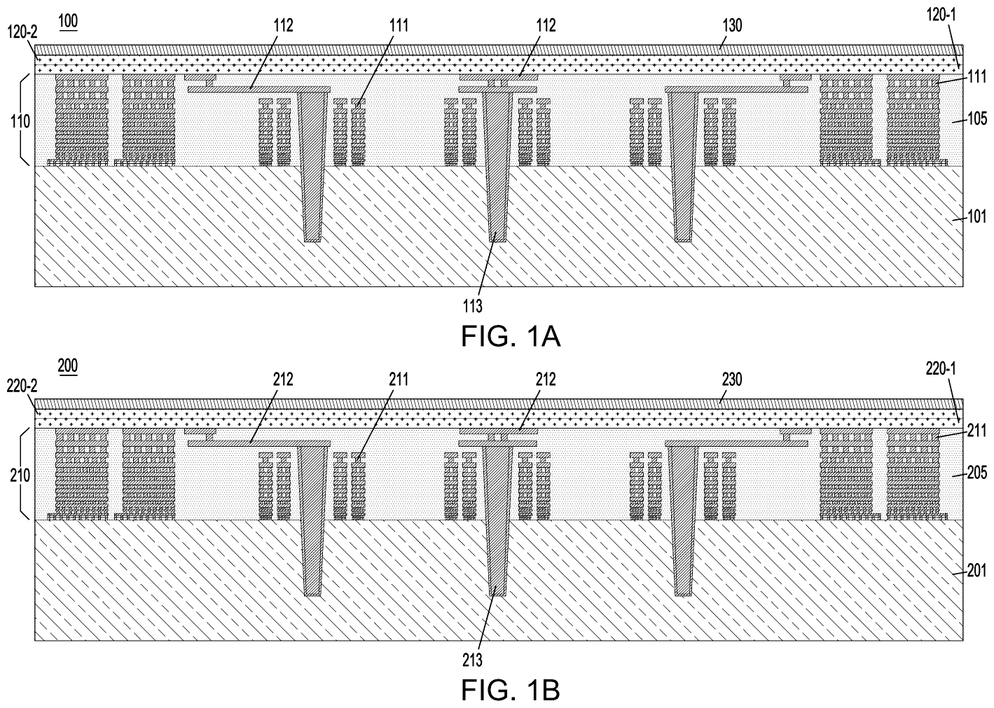

Referring to FIGS. 1A and 1B, a first semiconductor structure 100 and a second semiconductor structure 200 (or “first semiconductor die” and “second semiconductor die”) are formed on a first semiconductor substrate 101 and a second semiconductor substrate 201, respectively. A first semiconductor substrate 101 and a second semiconductor substrate 201 include semiconductor materials including, but not limited to, silicon, III-V, II-V compound semiconductor materials or other like semiconductor materials. In addition, multiple layers of the semiconductor materials can be used as the semiconductor material of the first and second semiconductor substrates 101 and 201.

The first and second semiconductor structures 100 and 200 respectively include a plurality of first metallization levels 110 and a plurality of second metallization levels 210 (e.g., FEOL, MOL and BEOL metallization levels) in a first dielectric layer stack 105 and a second dielectric layer stack 205. The first and second dielectric layer stacks 105 and 205 include, but are not necessarily limited to, tetraethyl orthosilicate (TEOS), silicon dioxide (SiO₂), carbon-doped silicon oxide (SiCOH), SILK® dielectrics, and/or porous forms of these low-k dielectric films. The first and second dielectric layer stacks 105 and 205 include multiple layers of the same or different materials deposited in multiple deposition steps depending on the design and fabrication processes associated with the first and second semiconductor structures 100 and 200. As can be understood by one of ordinary skill in the art, the first and second dielectric layer stacks 105 and 205 can be on the first and second semiconductor substrates 101 and 201, with intervening layers (e.g., lower conductive lines, devices, etc.) between the first and second dielectric layer stacks 105 and 205 and the first and second semiconductor substrates 101 and 201. A plurality of devices can be on or within the first and second semiconductor substrates 101 and 201, such as, for example, transistors, capacitors, and resistors.

The first and second metallization levels 110 and 210 respectively include a plurality of first metal layers 112 and a plurality of second metal layers 212 as shown by the horizontal lines. The first and second metal layers 112 and 212 can include, for example, wiring that is present on a chip, including, for example, multiple metal levels corresponding to circuit wiring, bussing, power distribution, input-output (I/O), backside power rails or other voltage or signal sources, etc.

The first metal layers 112 are connected to each other by one or more first vias 111 and the second metal layers are connected to each other by one or more second vias 211. The first and second vias 111 and 211 are illustrated as vertical lines between the horizontal lines representing the first and second metal layers 112 and 212. In addition, one or more of first TSVs 113 and second TSVs 213 can connect upper metal layers to lower metal layers and/or metal layers to circuits (not shown) of the first and second semiconductor structures 100 and 200. In illustrative embodiments, the first and second vias 111 and 211, the first and second metal layers 112 and 212, and the first and second TSVs 113 and 213 include, for example, a silicide layer, such as a silicide formed with Ni, Ti, NiPt, etc., a metal adhesion layer, such as TiN, and a conductive metal fill layer, such as Cu, W, Al, Co, Ru, etc., and can be deposited using, for example, a deposition technique such as chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), liquid source misted chemical deposition (LSMCD), sputtering and/or plating, followed by a planarization process such as, chemical mechanical planarization (CMP) to remove excess portions of the metal material from on top of dielectric layers.

As shown in FIGS. 1A and 1B, a first lower hybrid bonding level dielectric layer 120-1 and a first upper hybrid bonding level dielectric layer 120-2 (collectively, “first hybrid bonding level dielectric layers 120”) are deposited on the top surface of the first dielectric layer stack 105. Similarly, a second lower hybrid bonding level dielectric layer 220-1 and a second upper hybrid bonding level dielectric layer 220-2 (collectively, “second hybrid bonding level dielectric layers 220”) are deposited on the top surface of the second dielectric layer stack 205. The first and second hybrid bonding level dielectric layers 120 and 220 include, but are not necessarily limited to, TEOS, silicon-carbon-nitride (SiCN), and/or other dielectric films. A first photoresist 130 and a second photoresist 230 are respectively deposited on first and second upper hybrid bonding level dielectric layers 120-2 and 220-2.

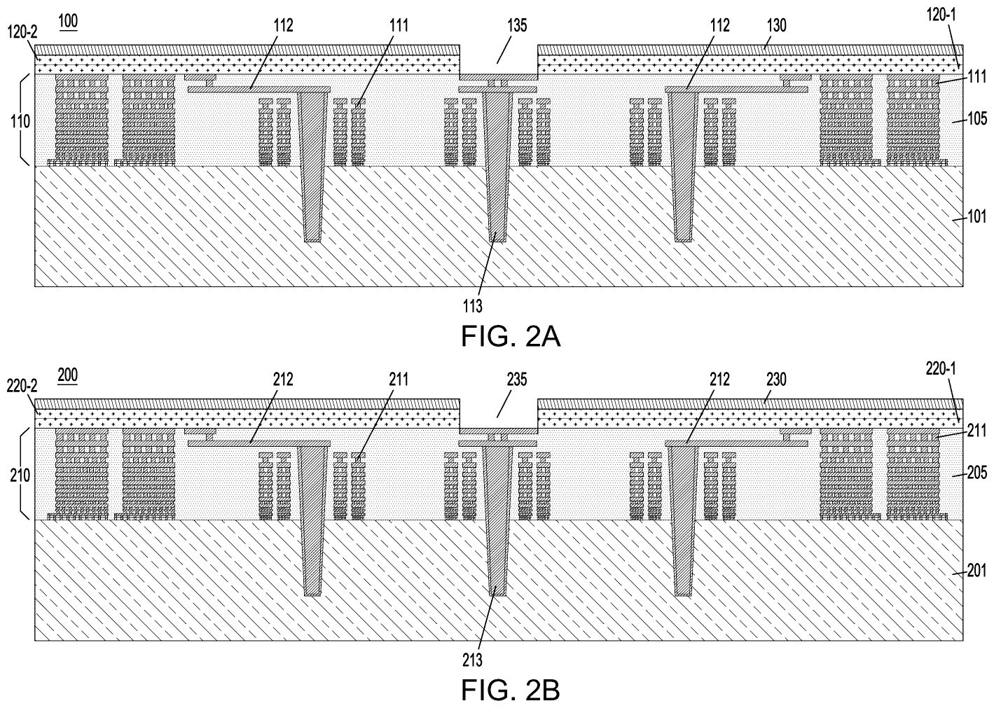

Referring to FIGS. 2A and 2B, the first and second photoresists 130 and 230 are patterned to create openings corresponding to where high-K dielectric capacitor regions are to be formed. The openings in the first and second photoresists 130 and 230 expose portions of the first and second hybrid bonding level dielectric layers 120 and 220 that are etched to create first and second openings 135 and 235 exposing an upper one of the first metal layers 112 and an upper one of the second metal layers 212. The etch can be performed using a reactive ion etching (RIE) process.

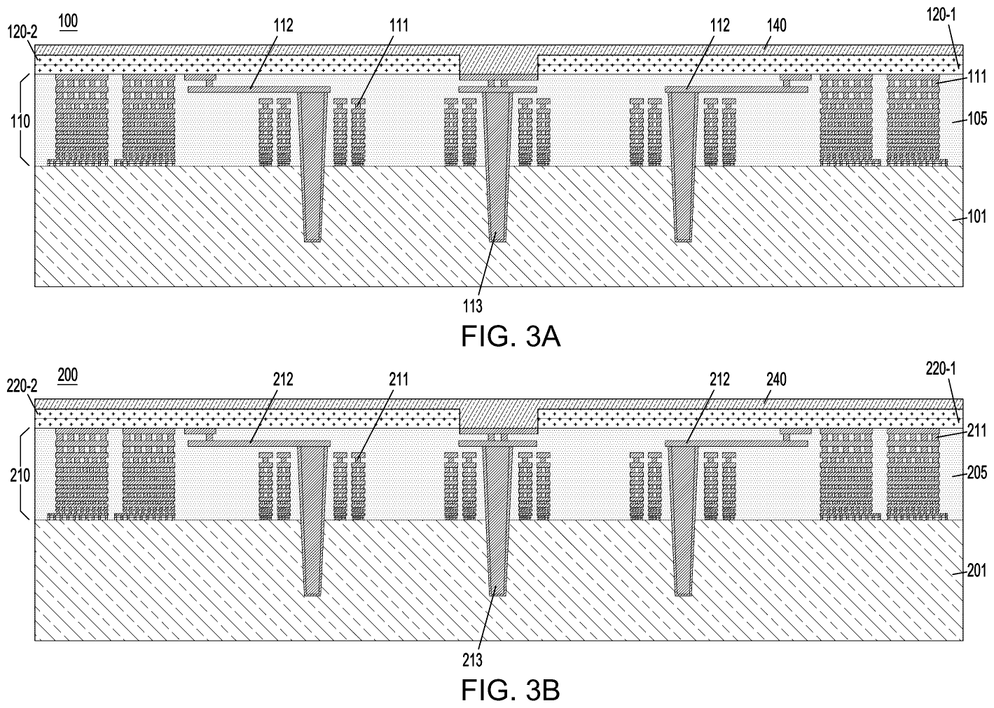

Referring to FIGS. 3A and 3B, following etching of the exposed portions of the first and second hybrid bonding level dielectric layers 120 and 220, the first and second photoresists 130 and 230 are removed and a first high-K dielectric layer 140 and a second high-K dielectric layer 240 are deposited on the resulting structures. According to illustrative embodiments, the material of the first and second high-K dielectric layers 140 and 240 includes, but is not necessarily limited to, one or more of HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. In an illustrative embodiment, first high-K dielectric layer 140 is formed from a different high-K dielectric material or materials from the high-K dielectric material or materials of the second high-K dielectric layer 240.

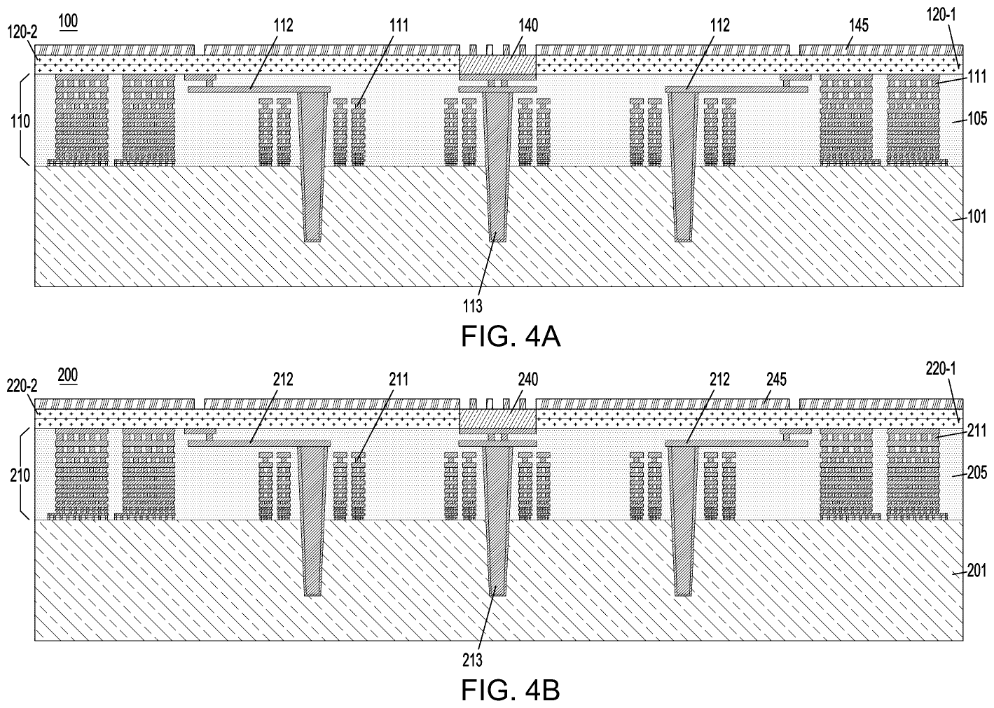

Referring to FIGS. 4A and 4B, following the deposition of the first high-K dielectric layer 140 and the second high-K dielectric layer 240, the first high-K dielectric layer 140 and the second high-K dielectric layer 240 are planarized using, for example, a CMP process to remove portions of the first high-K dielectric layer 140 and the second high-K dielectric layer 240 from the top surfaces of the first and second upper hybrid bonding level dielectric layers 120-2 and 220-2. Then, a first additional photoresist 145 and a second additional photoresist 245 are formed on the first and second upper hybrid bonding level dielectric layers 120-2 and 220-2 and remaining portions of the first high-K dielectric layer 140 and the second high-K dielectric layer 240. The first additional photoresist 145 and the second additional photoresist 245 are patterned to create openings exposing portions of the first and second upper hybrid bonding level dielectric layers 120-2 and 220-2 and portions of the first high-K dielectric layer 140 and the second high-K dielectric layer 240.

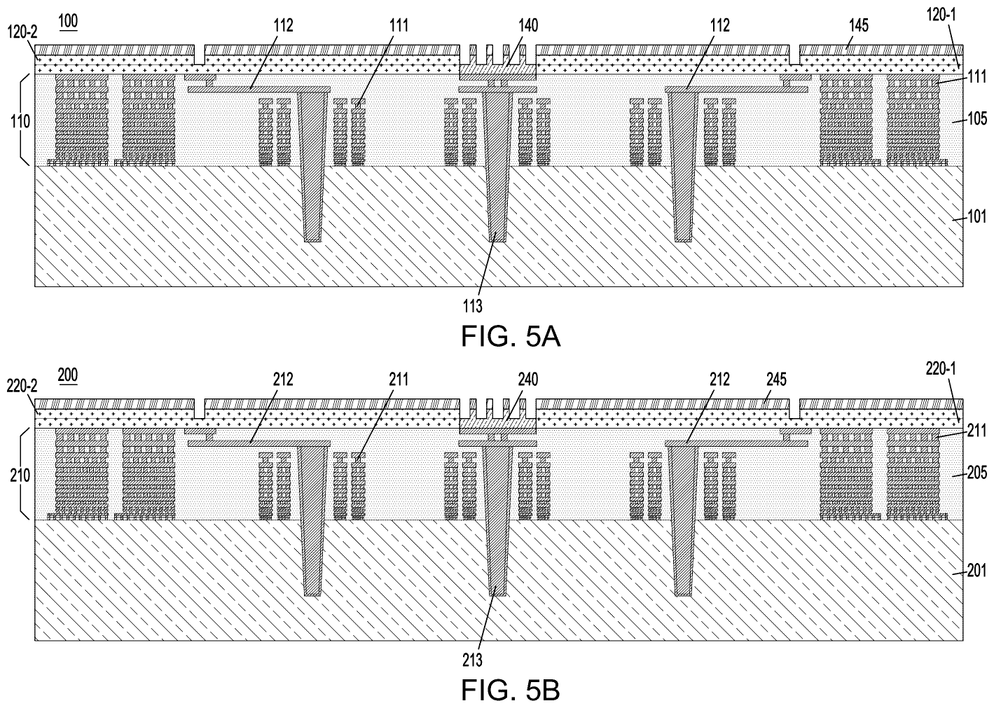

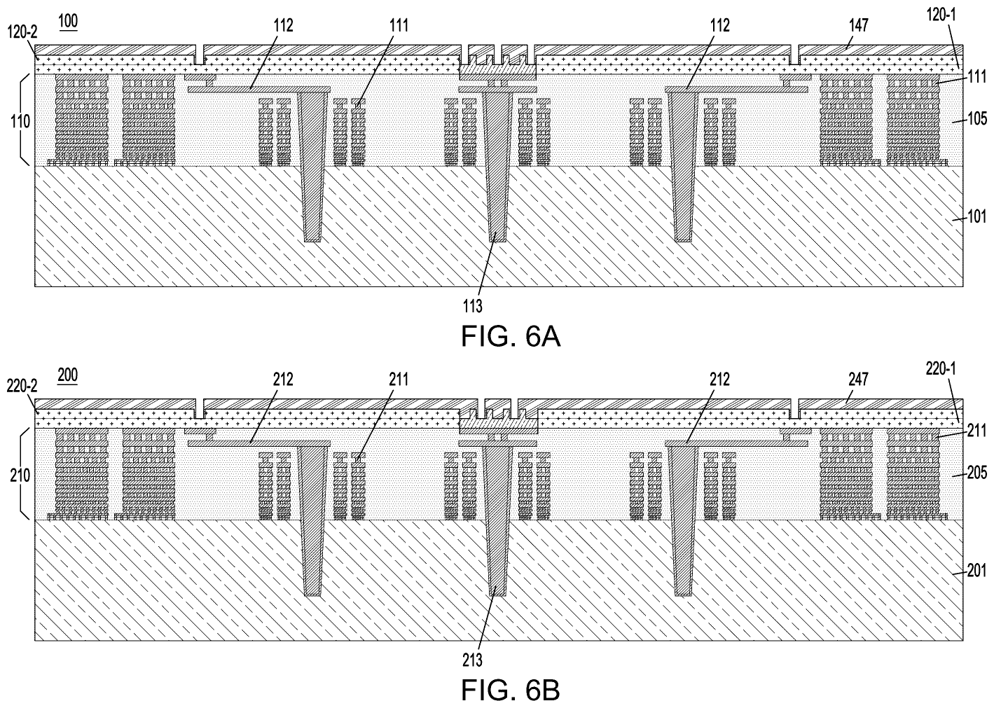

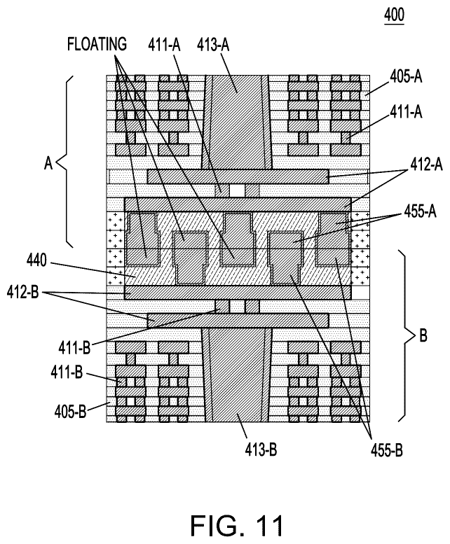

Referring to FIGS. 5A and 5B, exposed portions of the first and second hybrid upper bonding level dielectric layers 120-2 and 220-2 and portions of the first high-K dielectric layer 140 and the second high-K dielectric layer 240 are etched in, for example, an RIE process. As can be seen, the exposed portions of the first high-K dielectric layer 140 and the second high-K dielectric layer 240 are etched to point where their top surfaces are level with or substantially level with top surfaces the first and second lower hybrid bonding level dielectric layers 120-1 and 220-1. Then, referring to FIGS. 6A and 6B, the first additional photoresist 145 and the second additional photoresist 245 are removed, and a first final photoresist 147 and a second final photoresist 247 are formed on the first and second upper hybrid bonding level dielectric layers 120-2 and 220-2, on exposed portions of the first and second lower hybrid bonding level dielectric layers 120-1 and 220-1 and remaining portions of the first high-K dielectric layer 140 and the second high-K dielectric layer 240. The first final photoresist 147 and the second final photoresist 247 are patterned to create openings exposing portions of the first and second lower hybrid bonding level dielectric layers 120-1 and 220-1 and portions of the first high-K dielectric layer 140 and the second high-K dielectric layer 240. As can be seen in FIGS. 6A and 6B, the exposed portions of the first high-K dielectric layer 140 are complementary to the exposed portions of the second high-K dielectric layer 240, which facilitates formation of an alternating configuration of metal pads as explained in more detail herein below in connection with FIG. 11.

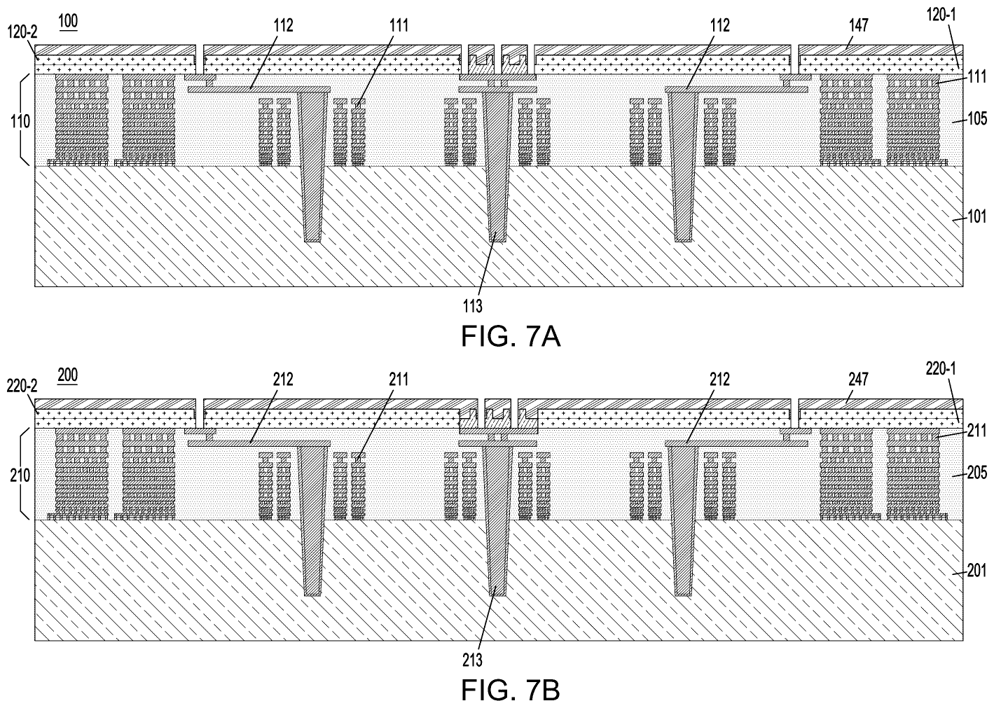

Referring to FIGS. 7A and 7B, the exposed portions of the first and second lower hybrid bonding level dielectric layers 120-1 and 220-1 and the exposed portions of the first high-K dielectric layer 140 and the second high-K dielectric layer 240 are etched in, for example, an RIE process. As can be seen, the exposed portions of the first and second lower hybrid bonding level dielectric layers 120-1 and 220-1 and the exposed portions of the first high-K dielectric layer 140 and the second high-K dielectric layer 240 are etched to point where portions of the underlying first and second metal layers 112 and 212 are exposed.

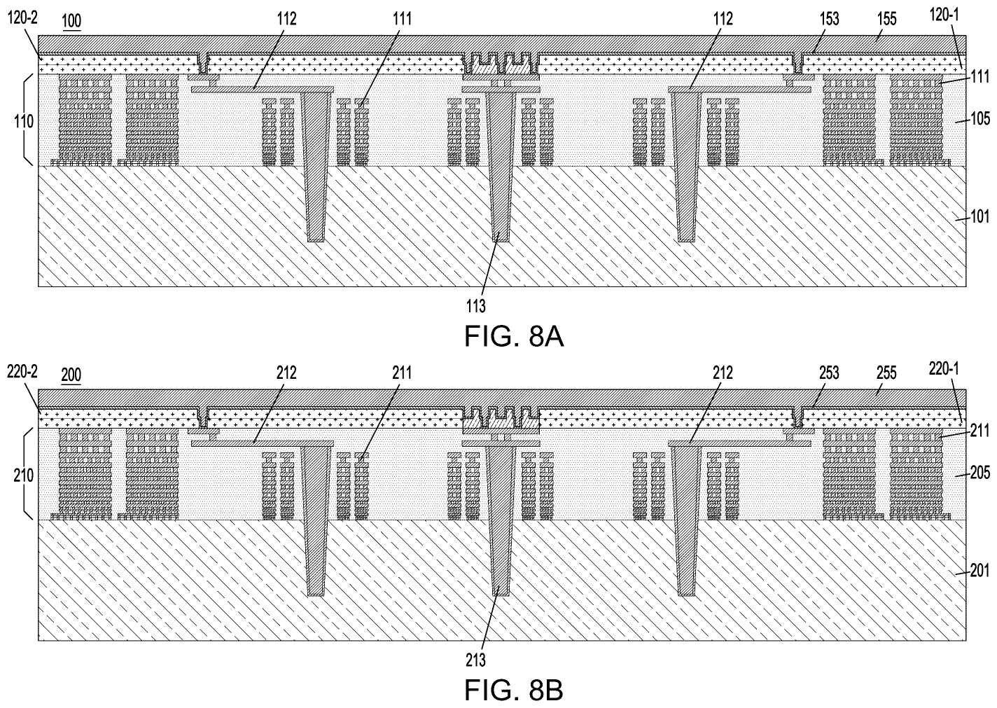

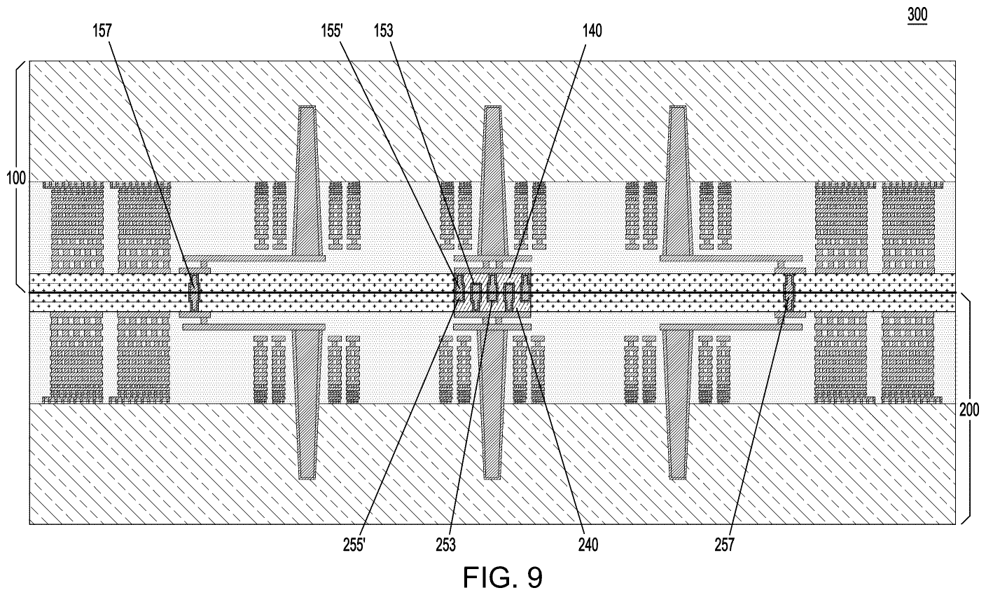

Referring to FIGS. 8A and 8B, the first and second final photoresists 147 and 247 are removed. A first seed/liner layer 153 is deposited on the remaining portions of the first hybrid bonding level dielectric layers 120, first high-K dielectric layer 140 and the exposed portions of the first metal layers 112. Similarly, a second seed/liner layer 253 is deposited on the remaining portions of the second hybrid bonding level dielectric layers 220, the second high-K dielectric layer 240 and the exposed portions of the second metal layers 212. According to illustrative embodiments, the first and second seed/liner layers 153 and 253 each include, for example, Ti/TiW, Ti/TiN, Ta/TaN, TaN/Co, CuMn, Cu and other copper alloys. Following deposition of the first and second seed/liner layers 153 and 253, a first metal fill layer 155 is formed on the first seed/liner layer 153 and a second metal fill layer 255 is formed on the second seed/liner layer 253. As can be seen in FIGS. 8A and 8B, the first and second metal fill layers 155 and 255 fill-in the remaining portions of the openings in the first and second hybrid bonding level dielectric layers 120 and 220, and the remaining portions of the openings in the first and second high-K dielectric layers 140 and 240. In illustrative embodiments, the metal fill layers are formed in a plating process or other deposition process noted herein above for metal deposition, and include, for example, Cu, W, Al, Co, Ru, etc.

Using, for example, CMP, the first and second metal fill layers 155 and 255, and the first and second seed/liner layers 153 and 253 are planarized from top surfaces first and second upper hybrid bonding level dielectric layers 120-2 and 220-2, and from top surfaces of the first and second high-K dielectric layers 140 and 240. Then, referring to FIG. 9, in a semiconductor device 300, the first semiconductor structure 100 is flipped (e.g., rotated 180 degrees) onto the second semiconductor structure 200 so that the first semiconductor structure 100 faces the second semiconductor structure 200. As used herein, the terms “face,” “faces” or “facing” refer to the result of rotating one of two structures 180 degrees so that top surfaces of the structures can be positioned opposite and aligned with each other.

In flipping the first semiconductor structure 100 onto the second semiconductor structure 200, first capacitor region metal pads 155′ of the first semiconductor structure 100 are aligned with second capacitor region metal pads 255′ of the second semiconductor structure 200. In addition, first signal metal pads 157 of the first semiconductor structure 100 are aligned with second signal metal pads 257 of the second semiconductor structure 200. As can be seen in FIG. 9, a first group of the first capacitor region metal pads 155′ (group A) are connected to a first metal layer 112 above the first high-K dielectric layer 140, while a second group of the first capacitor region metal pads 155′ (group B) are electrically isolated from the first metal layers 112 (e.g., floating). Respective first capacitor region metal pads 155′ in group A are in an alternating configuration with respective first capacitor region metal pads 155′ in group B. Similarly, in the second semiconductor structure 200, a first group of the second capacitor region metal pads 255′ (group C) are connected to a second metal layer 212 below the second high-K dielectric layer 240, while a second group of the second capacitor region metal pads 255′ (group D) are electrically isolated from the second metal layers 212 (e.g., floating). Respective second capacitor region metal pads 255′ in group C are in an alternating configuration with respective second capacitor region metal pads 255′ in group D. Further, the respective first capacitor region metal pads 155′ in group A are disposed opposite to respective second capacitor region metal pads 255′ in group D, and respective first capacitor region metal pads 155′ in group B are disposed opposite to respective second capacitor region metal pads 255′ in group C. The first capacitor region metal pads 155′ are embedded in the first high-K dielectric layer 140, and the second capacitor region metal pads 255′ are embedded in the second high-K dielectric layer 240.

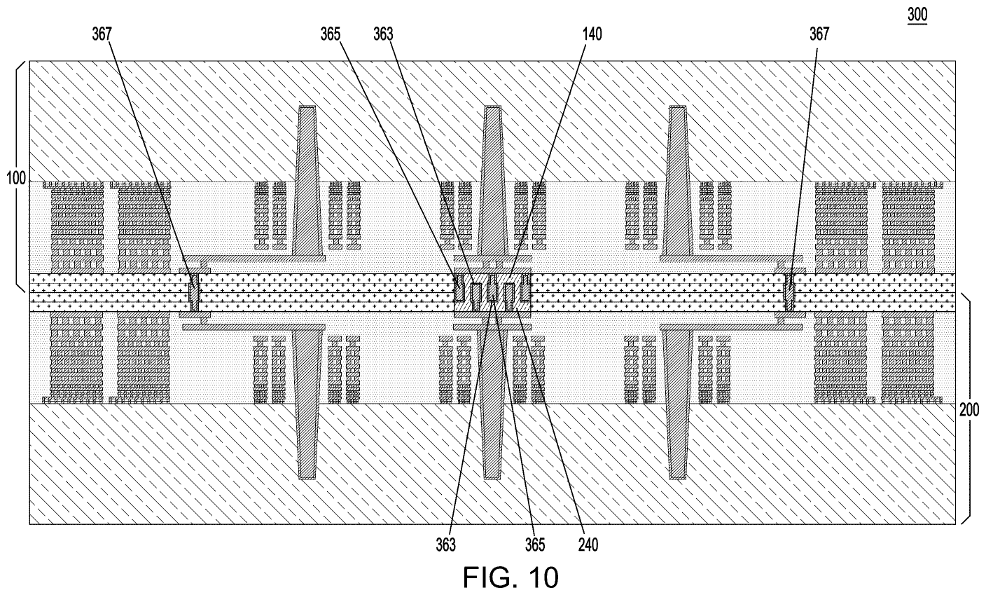

A heat treatment process is performed on the semiconductor device to anneal the metal material of the first capacitor region metal pads 155′, the second capacitor region metal pads 255′, the first signal metal pads 157 and the second signal metal pads 257 of FIG. 9. The heat treatment completes the hybrid bonding process. Referring to FIG. 10, as a result of the annealing, the opposing first and second capacitor region metal pads 155′ and 255′ are formed (e.g., integrated) into respective metal structures 365 (also referred to herein as “metal pads”) that span (e.g., bridge) across an interface between the first and second semiconductor structures 100 and 200. The metal structures 365 are lined with a heat treated seed/liner layer 363. Adjacent ones of the metal structures 365 in a left-to-right direction (e.g., horizontal direction in FIG. 10) are respectively connected to a first metal layer 112 of the first semiconductor structure 100 and a second metal layer 212 of the second semiconductor structure 200 in an alternating configuration. The respective metal structures 365 in combination with the first and second high-K dielectric layers 140 and 240 form a high capacitance capacitor structure including at least one capacitor. The high capacitance capacitor structure may include a plurality of capacitors. The metal structures 365 are embedded in the first and second high-K dielectric layers 140 and 240.

As a result of the annealing, the opposing first and second signal metal pads 157 and 257 are formed (e.g., integrated) into respective signal metal structures 367 (also referred to herein as “signal metal pads”) that span (e.g., bridge) across an interface between the first and second semiconductor structures 100 and 200. The conditions of the heat treatment process include, for example, heat treating at about 200° C. to about 400° C. for about 1 hour to 3 hours. In an illustrative embodiment, the heat treatment is performed at 300° C. to about 400° C. for about 1 hour to about 2 hours.

Similar to what is shown in FIG. 9, FIG. 11 depicts a cross-sectional view of semiconductor device 400 with a hybrid bonding high-K dielectric capacitor region. In more detail, a first semiconductor structure A has been flipped and is positioned on top of a second semiconductor structure B so that in a hybrid bonding high-K dielectric capacitor region, first metal pads 455-A of the first semiconductor structure A are in alignment with second metal pads 455-B of the second semiconductor structure B. Similar to the semiconductor device 300 in FIG. 9, some of the first and second metal pads 455-A and 455-B are floating, while others of the first and second metal pads 455-A and 455-B are connected to first metal layers 412-A and second metal layers 412-B, respectively. The electrically connected and floating first metal pads 455-A are in an alternating configuration, and the electrically connected and floating second metal pads 455-B are in an alternating configuration opposite to that of the first metal pads 455-A. The semiconductor device 400 includes a first TSV 413-A connected to first metal layers 412-A that are connected to the first metal pads 455-A, and a second TSV 413-B connected to second metal layers 412-B that are connected to the second metal pads 455-B. The first and second metal pads 455-A and 455-B are embedded in a high-K dielectric layer 440, which can include two different high-K dielectric materials. The first semiconductor structure A includes multiple dielectric layers 405-A similar to first and second dielectric layer stacks 105 and 205, in which a plurality of first metal layers 412-A and first vias 411-A (similar to first metal layers 112 and first vias 111) are formed. The second semiconductor structure B includes multiple dielectric layers 405-B similar to first and second dielectric layer stacks 105 and 205, in which a plurality of second metal layers 412-B and second vias 411-B (similar to second metal layers 212 and second vias 211) are formed.

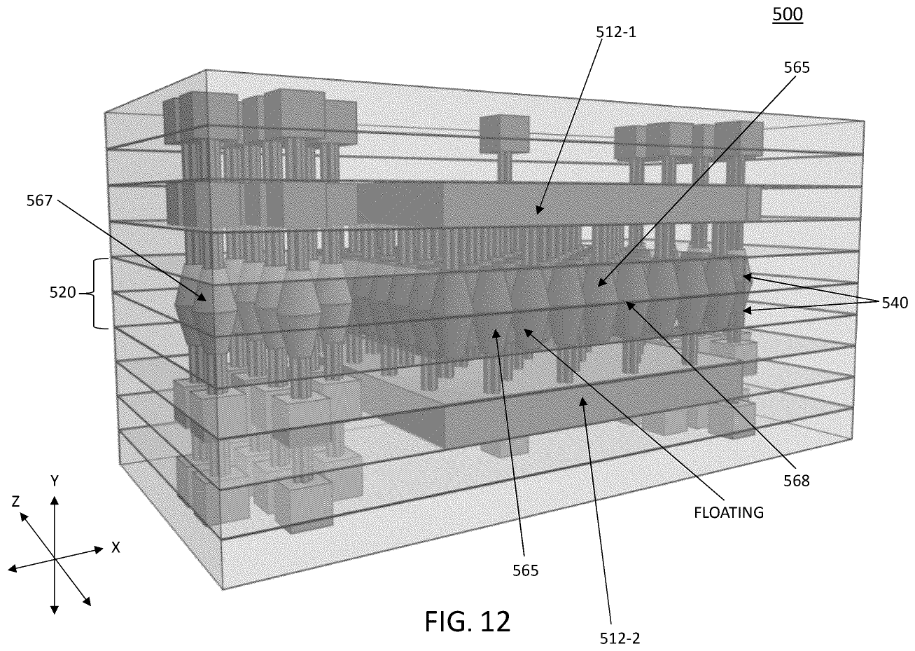

Referring to FIG. 12, a three-dimensional view of a semiconductor device 500 including a hybrid bonded high-K dielectric capacitor region and a hybrid bonded signal metal pad region is shown. In the hybrid bonded high-K dielectric capacitor region, similar to the metal structures 365 of semiconductor device 300 in FIG. 10, the semiconductor device 500 includes respective metal structures 565 (also referred to herein as “metal pads”) that are embedded in high-K dielectric material 540 and span (e.g., bridge) across an interface 568 between the two semiconductor structures. Adjacent ones of the metal structures 565 in an x-direction and z-direction in FIG. 12 are respectively connected to a first metal layer 512-1 and a second metal layer 512-2 in an alternating configuration. The respective metal structures 565 in combination with the high-K dielectric material 540 form a high capacitance capacitor structure including at least one capacitor. As indicated in FIG. 12, some of the metal structures are floating with respect to a first or second metal layer 512-1 or 512-2.

In the hybrid bonded signal metal pad region, like the signal metal structures 367 in the semiconductor device 300, respective signal metal structures 567 (also referred to herein as “signal metal pads”) span (e.g., bridge) across an interface between first and second semiconductor structures and are formed in one or more low-K dielectric layers 520. The signal metal structures 367 and 567 are not capacitors and transfer signals (e.g., voltage output) between metal layers (e.g., in the y-direction in FIG. 12).

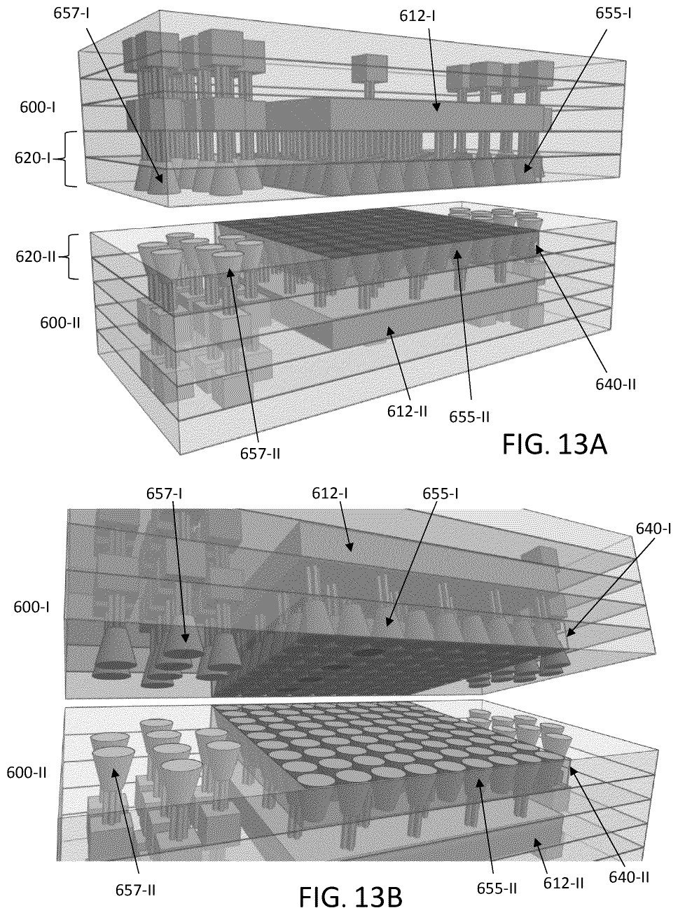

FIGS. 13A and 13B depict three-dimensional views of first and second semiconductor structures each including a hybrid bonding high-K dielectric capacitor region and a hybrid bonding metal pad region. In more detail, a first semiconductor structure 600-I has been flipped and is positioned on top of a second semiconductor structure 600-II so that in a hybrid bonding high-K dielectric capacitor region, first metal pads 655-I of the first semiconductor structure 600-I are in alignment with second metal pads 655-II of the second semiconductor structure 600-II. Similar to the semiconductor device 300 in FIG. 9, some of the first and second metal pads 655-I and 655-II are floating, while others of the first and second metal pads 655-I and 655-II are connected to first metal layer 612-I and second metal layer 612-II, respectively. The electrically connected and floating first metal pads 655-I are in an alternating configuration, and the electrically connected and floating second metal pads 655-II are in an alternating configuration opposite to that of the first metal pads 655-I. The first metal pads 655-I are embedded in a first high-K dielectric layer 640-I, and the second metal pads 655-II are embedded in a second high-K dielectric layer 640-II. The first and second high-K dielectric layers 640-I and 640-II can include different high-K dielectric materials from each other.

In the hybrid bonded signal metal pad region, first signal metal pads 657-I in first low-K dielectric layers 620-I of the first semiconductor structure 600-I are aligned with second signal metal pads 657-II in second low-K dielectric layers 620-II of the second semiconductor structure 600-II.

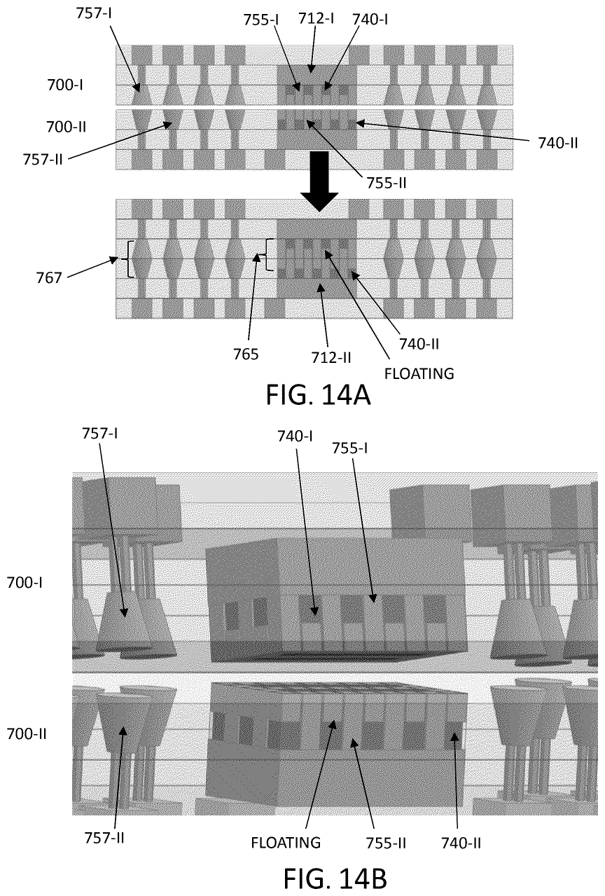

FIGS. 14A and 14B respectively depict cross-sectional and three-dimensional views illustrating a hybrid bonding process of two semiconductor structures to create a single structure including hybrid bonding high-K dielectric capacitor and hybrid bonding metal pad regions. In more detail, a first semiconductor structure 700-I has been flipped and is positioned on top of a second semiconductor structure 700-II so that in a hybrid bonding high-K dielectric capacitor region, first metal pads 755-I of the first semiconductor structure 700-I are in alignment with second metal pads 755-II of the second semiconductor structure 700-II. Similar to the semiconductor device in FIGS. 13A and 13B, some of the first and second metal pads 755-I and 755-II are floating, while others of the first and second metal pads 755-I and 755-II are connected to first metal layer 712-I and second metal layer 712-II, respectively. The electrically connected and floating first metal pads 755-I are in an alternating configuration, and the electrically connected and floating second metal pads 755-II are in an alternating configuration opposite to that of the first metal pads 755-I. The first metal pads 755-I are embedded in a first high-K dielectric layer 740-I, and the second metal pads 755-II are embedded in a second high-K dielectric layer 740-II. The first and second high-K dielectric layers 740-I and 740-II can include different high-K dielectric materials from each other. In this embodiment, the first metal pads 755-I and the second metal pads 755-II have rectangular or square cross-sections instead of conical cross-sections as in the first metal pads 655-I and the second metal pads 655-II.

In the hybrid bonding signal metal pad region, first signal metal pads 757-I of the first semiconductor structure 700-I are aligned with second signal metal pads 757-II of the second semiconductor structure 700-II.

In the hybrid bonded high-K dielectric capacitor region as shown in the bottom half of FIG. 14A, similar to the metal structures 365 of semiconductor device 300 in FIG. 10 and the metal structures 565 of semiconductor device 500 in FIG. 12, respective metal structures 765 (also referred to herein as “metal pads”) are embedded in first and second high-K dielectric layers 740-I and 740-II and span (e.g., bridge) across an interface between the first and second semiconductor structures 700-I and 700-II. Adjacent ones of the metal structures 765 in a horizontal direction in FIG. 14A are respectively connected to a first metal layer 712-I and a second metal layer 712-II in an alternating configuration. The respective metal structures 765 in combination with the first and second high-K dielectric layers 740-I and 740-II form a high capacitance capacitor structure including at least one capacitor. As indicated in FIG. 14A, some of the metal structures 765 are floating with respect to a first or second metal layer 712-I or 712-II.

In the hybrid bonded signal metal pad region, like the signal metal structures 367 in the semiconductor device 300 and the signal metal structures 567 in the semiconductor device 500, respective signal metal structures 767 (also referred to herein as “signal metal pads”) span (e.g., bridge) across an interface between first and second semiconductor structures 700-I and 700-II and are formed in one or more low-K dielectric layers. The signal metal structures 767 are not capacitors and transfer signals (e.g., voltage output) between metal layers (e.g., in the vertical direction in FIG. 14A).

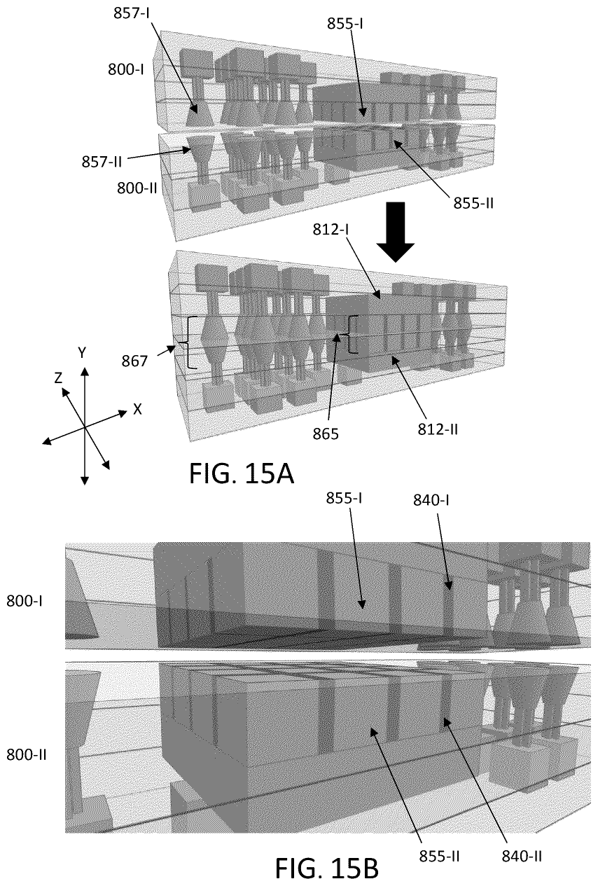

FIGS. 15A and 15B depict three-dimensional views illustrating a hybrid bonding process of two semiconductor structures to create a single structure including hybrid bonding high-K dielectric capacitor and hybrid bonding metal pad regions. In more detail, a first semiconductor structure 800-I has been flipped and is positioned on top of a second semiconductor structure 800-II so that in a hybrid bonding high-K dielectric capacitor region, first metal pads 855-I of the first semiconductor structure 800-I are in alignment with second metal pads 855-II of the second semiconductor structure 800-II. Unlike the semiconductor device in FIGS. 14A and 14B, none of the first and second metal pads 855-I and 855-II are floating, and all of the first and second metal pads 855-I and 855-II are connected to first metal layer 812-I and second metal layer 812-II, respectively. The first metal pads 855-I are embedded in a first high-K dielectric layer 840-I, and the second metal pads 855-II are embedded in a second high-K dielectric layer 840-II. The first and second high-K dielectric layers 840-I and 840-II can include different high-K dielectric materials from each other. In this embodiment, the first metal pads 855-I and the second metal pads 855-II have rectangular or square cross-sections instead of conical cross-sections as in the first metal pads 655-I and the second metal pads 655-II.

In the hybrid bonding signal metal pad region, first signal metal pads 857-I of the first semiconductor structure 800-I are aligned with second signal metal pads 857-II of the second semiconductor structure 800-II.

In the hybrid bonded high-K dielectric capacitor region as shown in the bottom half of FIG. 15A, respective metal structures 865 (also referred to herein as “metal pads”) are embedded in first and second high-K dielectric layers 840-I and 840-II and span (e.g., bridge) across an interface between the first and second semiconductor structures 800-I and 800-II. The metal structures 865 are connected to both the first metal layer 812-I and the second metal layer 812-II. The respective metal structures 865 in combination with the first and second high-K dielectric layers 840-I and 840-II form a high capacitance capacitor structure including at least one capacitor.

In the hybrid bonded signal metal pad region, like the signal metal structures 367 in the semiconductor device 300 and the signal metal structures 567 in the semiconductor device 500, respective signal metal structures 867 (also referred to herein as “signal metal pads”) span (e.g., bridge) across an interface between first and second semiconductor structures 800-I and 800-II and are formed in one or more low-K dielectric layers. The signal metal structures 867 are not capacitors and transfer signals (e.g., voltage output) between metal layers (e.g., in the y-direction in FIG. 15A).

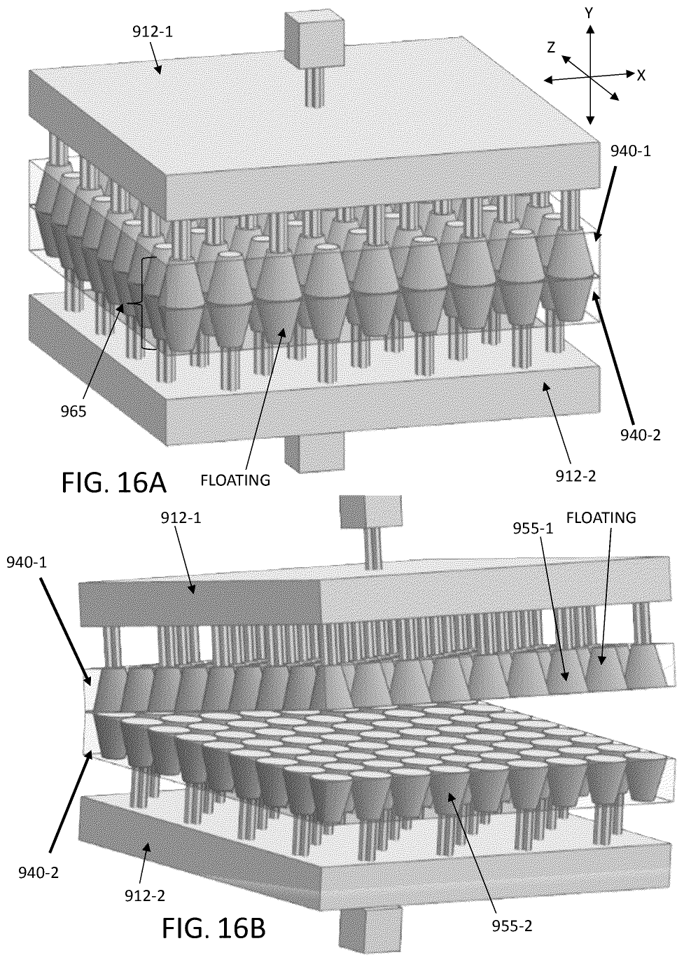

FIG. 16A depicts a three-dimensional view of a hybrid bonded high-K dielectric capacitor region, and FIG. 16B depicts a three-dimensional view of high-K dielectric capacitor regions prior to hybrid bonding, according to an embodiment of the invention. Referring to FIGS. 16A and 16B, a first semiconductor structure has been flipped and is positioned on top of a second semiconductor structure so that in a hybrid bonding high-K dielectric capacitor region, first metal pads 955-1 of the first semiconductor structure are in alignment with second metal pads 955-2 of the second semiconductor structure. Similar to the semiconductor device in FIGS. 13A and 13B, some of the first and second metal pads 955-1 and 955-2 are floating, while others of the first and second metal pads 955-1 and 955-2 are connected to first metal layer 912-1 and second metal layer 912-2, respectively. The electrically connected and floating first metal pads 955-1 are in an alternating configuration, and the electrically connected and floating second metal pads 955-2 are in an alternating configuration opposite to that of the first metal pads 955-1. The first metal pads 955-1 are embedded in a first high-K dielectric layer 940-1, and the second metal pads 955-2 are embedded in a second high-K dielectric layer 940-2. The first and second high-K dielectric layers 940-1 and 940-2 can include different high-K dielectric materials from each other. In this embodiment, the first metal pads 955-I and the second metal pads 955-II have conical cross-sections.

In the hybrid bonded high-K dielectric capacitor region as shown in FIG. 16A, similar to the metal structures 365 of semiconductor device 300 in FIG. 10 and the metal structures 565 of semiconductor device 500 in FIG. 12, respective metal structures 965 (also referred to herein as “metal pads”) are embedded in first and second high-K dielectric layers 940-1 and 940-2 and span (e.g., bridge) across an interface between first and second semiconductor structures. Adjacent ones of the metal structures 965 in the x and z-directions in FIG. 16A are respectively connected to a first metal layer 912-1 and the second metal layer 912-2 in an alternating configuration. The respective metal structures 965 in combination with the first and second high-K dielectric layers 940-1 and 940-2 form a high capacitance capacitor structure including at least one capacitor. As indicated in FIG. 16A, some of the metal structures 965 are floating with respect to a first or second metal layer 912-1 or 912-2.

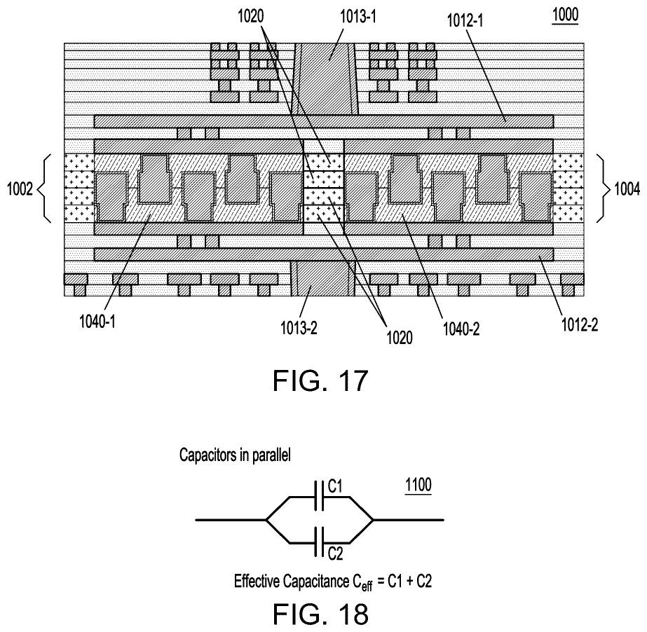

FIG. 17 depicts a cross-sectional view of first and second hybrid bond high-K dielectric capacitor structures 1002 and 1004 connected in parallel. In a semiconductor device 1000, the first and second hybrid bond high-K dielectric capacitor structures 1002 and 1004 are in respective high-K dielectric layers 1040-1 and 1040-2 and a plurality of low-K dielectric layers 1020 are disposed between the first and second hybrid bond high-K dielectric capacitor structures 1002 and 1004. The first and second hybrid bond high-K dielectric capacitor structures 1002 and 1004 are connected in parallel to top and bottom metal layers 1012-1 and 1012-2, which are respectively connected to top and bottom TSVs 1013-1 and 1013-2. As can be seen in the circuit diagram 1100 in FIG. 18, when capacitors are connected in parallel, the effective capacitance is additive (e.g., the sum of the capacitance of each capacitor connected in parallel).

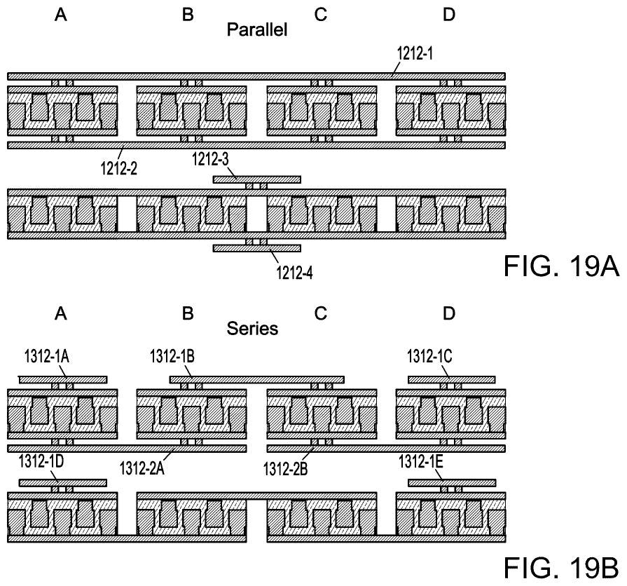

FIG. 19A depicts a cross-sectional view of multiple hybrid bond high-K dielectric capacitor structures connected in parallel. As can be seen in FIG. 19A, in one configuration, four hybrid bond high-K dielectric capacitor structures A, B, C and D are connected in parallel to metal layers 1212-1 and 1212-2, and in another configuration, the four hybrid bond high-K dielectric capacitor structures A, B, C and D are connected in parallel to metal layers 1212-3 and 1212-4. FIG. 19B depicts a cross-sectional view of multiple hybrid bond high-K dielectric capacitor structures connected in series. As can be seen in FIG. 19B, in one configuration, four hybrid bond high-K dielectric capacitor structures A, B, C and D are connected in series to metal layers 1312-1A, 1312-1B and 1312-1C, and to metal layers 1312-2A and 1312-2B. In another configuration, the four hybrid bond high-K dielectric capacitor structures A, B, C and D are connected in series to metal layers 1312-1D and 1312-1E. Connecting several capacitors in series can result in a functional block or capacitive voltage divider. When the block is connected to a voltage source, each capacitor in the block stores an equal amount of charge, which means that the total amount of charge is evenly distributed across all of the capacitors, regardless of their capacitance. A series connection of capacitors can be used when working with higher voltages. When capacitors are placed in series, voltage increases.

In one embodiment, a semiconductor device includes a first semiconductor structure bonded to a second semiconductor structure; and a plurality of metal pads at an interface portion between the first semiconductor structure and the second semiconductor structure. The plurality of metal pads are disposed in a high-K dielectric layer. The plurality of metal pads and the high-K dielectric layer include at least one capacitor.

The first semiconductor structure may be hybrid bonded to the second semiconductor structure. The first semiconductor structure may include a first metal layer connected to at least a first voltage source. A first subset of the plurality of metal pads may be connected to the first metal layer, and a second subset of the plurality of metal pads may be electrically isolated from the first metal layer.

The second semiconductor structure may include a second metal layer connected to at least a second voltage source. The first subset of the plurality of metal pads may be electrically isolated from the second metal layer, and the second subset of the plurality of metal pads may be connected to the second metal layer. Respective ones of metal pads in the first subset of the plurality of metal pads may be disposed in an alternating configuration with respective ones of metal pads in the second subset of the plurality of metal pads.

The first semiconductor structure may include a first metal layer connected to at least a first voltage source, and the second semiconductor structure may include a second metal layer connected to at least a second voltage source. At least some of the plurality of metal pads may be floating with respect to one of the first metal layer and the second metal layer.

The high-K dielectric layer may include at least two high-K dielectric materials that are different from each other. A second plurality of metal pads may be disposed at a second interface portion between the first semiconductor structure and the second semiconductor structure, wherein the second plurality of metal pads are disposed in a second high-K dielectric layer. The second plurality of metal pads and the second high-K dielectric layer may include at least one other capacitor. The at least one capacitor and the at least one other capacitor may be connected to each other in parallel or in series.

A second plurality of metal pads may be disposed at a second interface portion between the first semiconductor structure and the second semiconductor structure, wherein the second plurality of metal pads are disposed in a low-K dielectric layer, and the second plurality of metal pads include signal lines.

In another embodiment, a semiconductor device includes a first semiconductor die including a first plurality of metal pads disposed in a first high-K dielectric layer, and a second semiconductor die including a second plurality of metal pads disposed in a second high-K dielectric layer. The first semiconductor die is bonded to the second semiconductor die. Respective ones of the first plurality of metal pads are aligned with respective ones of the second plurality of metal pads. The first and second plurality of metal pads and the first and second high-K dielectric layers form at least one capacitor.

A material of the first high-K dielectric layer may be different from a material of the second high-K dielectric layer. A subset of the plurality of first metal pads may be floating with respect to a voltage source of the first semiconductor die, and a subset of the plurality of second metal pads may be floating with respect to a voltage source of the second semiconductor die.

In another embodiment, an apparatus includes two or more semiconductor dies hybrid bonded together, and a plurality of metal structures at an interface portion between a first semiconductor die of the two or more semiconductor dies and a second semiconductor die of the two or more semiconductor dies. The plurality of metal structures are disposed in at least one high-K dielectric layer, wherein the plurality of metal structures and the at least one high-K dielectric layer include at least one capacitor.

The first semiconductor die may include a first metal layer connected to at least a first voltage source. A first subset of the plurality of metal structures may be connected to the first metal layer, and a second subset of the plurality of metal structures may be electrically isolated from the first metal layer. The second semiconductor die may include a second metal layer connected to at least a second voltage source. The first subset of the plurality of metal structures may be electrically isolated from the second metal layer, and the second subset of the plurality of metal structures may be connected to the second metal layer. Respective ones of metal structures in the first subset of the plurality of metal structures may be disposed in an alternating configuration with respective ones of metal structures in the second subset of the plurality of metal structures.

The at least one high-K dielectric layer may include at least a first high-K dielectric layer including a first high-K dielectric material and a second high-K dielectric layer including a second high-k dielectric material different from the first high-K dielectric material.

In another embodiment, an apparatus includes a first semiconductor structure disposed on top of and facing a second semiconductor structure, wherein the first semiconductor structure and the second semiconductor structure are bonded to each other. A plurality of metal structures span an interface portion between the first semiconductor structure and the second semiconductor structure, wherein the plurality of metal structures are disposed in at least one high-K dielectric layer, and the plurality of metal structures and the at least one high-K dielectric layer include at least one capacitor.

A second plurality of metal structures may span a second interface portion between the first semiconductor structure and the second semiconductor structure. The second plurality of metal structures may be disposed in at least one second high-K dielectric layer, wherein the second plurality of metal structures and the at least one second high-K dielectric layer include at least one other capacitor. The at least one capacitor and the at least one other capacitor may be connected to each other in parallel.

In another embodiment, a method includes forming a first semiconductor structure on a first semiconductor substrate, wherein the first semiconductor structure includes a first plurality of metal pads disposed in a first high-K dielectric layer, and forming a second semiconductor structure on a second semiconductor substrate, wherein the second semiconductor structure includes a second plurality of metal pads disposed in a second high-K dielectric layer. Respective ones of the first plurality of metal pads are aligned with respective ones of the second plurality of metal pads. A thermal treatment process is performed to bond the first semiconductor structure to the second semiconductor structure, wherein the thermal treatment process integrates the first plurality of metal pads with the second plurality of metal pads to create a plurality of metal structures spanning an interface between the first semiconductor structure to the second semiconductor structure. The plurality of metal structures and the first and second high-K dielectric layers form at least one capacitor.

A material of the first high-K dielectric layer may be different from a material of the second high-K dielectric layer. The thermal treatment process may anneal the first plurality of metal pads and the second plurality of metal pads.

It is to be appreciated that the hybrid bonding techniques as disclosed herein enable construction of high capacitance structure which provides various advantages over conventional 2-D and 3-D packaging structures and techniques as discussed above. For example, the structure advantageously uses metallic bonding pads embedded within high-K dielectric material at joining surfaces/interface portions that when brought together in a bonding process form a complete capacitor structure. As described in detail herein, some of the embedded metallic bonding pads are connected to metallic plates and wiring (e.g., metal layers), while some of the embedded metallic bonding pads are floating (e.g., dummy pads), that complement the configuration of the connected bonding pads on the corresponding semiconductor build. When the two builds are bonded, the connected pads and the dummy pads create a singular metallic structure that bridges across the interface portion. The singular metallic structures have alternating orientations to create an interwoven pattern. As an additional advantage, resulting capacitor structures can be wired together in parallel hybrid bond interfaces to effectively increase capacitance.

Although exemplary embodiments have been described herein with reference to the accompanying figures, it is to be understood that the disclosure is not limited to those precise embodiments, and that various other changes and modifications may be made therein by one skilled in the art without departing from the scope of the appended claims.

What is claimed is:

1. A device, comprising:
a first semiconductor structure bonded to a second semiconductor structure; and
a plurality of metal pads at an interface portion between the first semiconductor structure and the second semiconductor structure;
wherein the plurality of metal pads are disposed in a high-K dielectric layer; and
wherein the plurality of metal pads and the high-K dielectric layer comprise at least one capacitor.

2. The device of claim 1, wherein the first semiconductor structure is hybrid bonded to the second semiconductor structure.

3. The device of claim 1, wherein:
the first semiconductor structure comprises a first metal layer connected to at least a first voltage source;
a first subset of the plurality of metal pads is connected to the first metal layer; and
a second subset of the plurality of metal pads is electrically isolated from the first metal layer.

4. The device of claim 3, wherein:
the second semiconductor structure comprises a second metal layer connected to at least a second voltage source;
the first subset of the plurality of metal pads is electrically isolated from the second metal layer; and
the second subset of the plurality of metal pads is connected to the second metal layer.

5. The device of claim 4, wherein respective ones of metal pads in the first subset of the plurality of metal pads are disposed in an alternating configuration with respective ones of metal pads in the second subset of the plurality of metal pads.

6. The device of claim 1, wherein:
the first semiconductor structure comprises a first metal layer connected to at least a first voltage source;
the second semiconductor structure comprises a second metal layer connected to at least a second voltage source; and
at least some of the plurality of metal pads are floating with respect to one of the first metal layer and the second metal layer.

7. The device of claim 1, wherein the high-K dielectric layer comprises at least two high-K dielectric materials that are different from each other.

8. The device of claim 1, further comprising:
a second plurality of metal pads at a second interface portion between the first semiconductor structure and the second semiconductor structure;
wherein the second plurality of metal pads are disposed in a second high-K dielectric layer; and
wherein the second plurality of metal pads and the second high-K dielectric layer comprise at least one other capacitor.

9. The device of claim 8, wherein the at least one capacitor and the at least one other capacitor are connected to each other in parallel.

10. The device of claim 8, wherein the at least one capacitor and the at least one other capacitor are connected to each other in series.

11. The device of claim 1, further comprising:
a second plurality of metal pads at a second interface portion between the first semiconductor structure and the second semiconductor structure;
wherein the second plurality of metal pads are disposed in a low-K dielectric layer; and
wherein the second plurality of metal pads comprise signal lines.

12. A device, comprising:
a first semiconductor die comprising a first plurality of metal pads disposed in a first high-K dielectric layer; and
a second semiconductor die comprising a second plurality of metal pads disposed in a second high-K dielectric layer;
wherein the first semiconductor die is bonded to the second semiconductor die;
wherein respective ones of the first plurality of metal pads are aligned with respective ones of the second plurality of metal pads; and
wherein the first and second plurality of metal pads and the first and second high-K dielectric layers form at least one capacitor.

13. The device of claim 12, wherein a material of the first high-K dielectric layer is different from a material of the second high-K dielectric layer.

14. The device of claim 12, wherein:
a subset of the plurality of first metal pads are floating with respect to a voltage source of the first semiconductor die; and
a subset of the plurality of second metal pads are floating with respect to a voltage source of the second semiconductor die.

15. An apparatus, comprising:
two or more semiconductor dies hybrid bonded together; and
a plurality of metal structures at an interface portion between a first semiconductor die of the two or more semiconductor dies and a second semiconductor die of the two or more semiconductor dies;
wherein the plurality of metal structures are disposed in at least one high-K dielectric layer; and
wherein the plurality of metal structures and the at least one high-K dielectric layer comprise at least one capacitor.

16. The apparatus of claim 15, wherein:
the first semiconductor die comprises a first metal layer connected to at least a first voltage source;
a first subset of the plurality of metal structures is connected to the first metal layer; and
a second subset of the plurality of metal structures is electrically isolated from the first metal layer.

17. The apparatus of claim 16, wherein:
the second semiconductor die comprises a second metal layer connected to at least a second voltage source;
the first subset of the plurality of metal structures is electrically isolated from the second metal layer; and
the second subset of the plurality of metal structures is connected to the second metal layer.

18. The apparatus of claim 17, wherein respective ones of metal structures in the first subset of the plurality of metal structures are disposed in an alternating configuration with respective ones of metal structures in the second subset of the plurality of metal structures.

19. The apparatus of claim 15, wherein the at least one high-K dielectric layer comprises at least a first high-K dielectric layer comprising a first high-K dielectric material and a second high-K dielectric layer comprising a second high-k dielectric material different from the first high-K dielectric material.

20. An apparatus, comprising:
a first semiconductor structure disposed on top of and facing a second semiconductor structure, wherein the first semiconductor structure and the second semiconductor structure are bonded to each other; and
a plurality of metal structures spanning an interface portion between the first semiconductor structure and the second semiconductor structure;
wherein the plurality of metal structures are disposed in at least one high-K dielectric layer; and
wherein the plurality of metal structures and the at least one high-K dielectric layer comprise at least one capacitor.

21. The apparatus of claim 20, further comprising:
a second plurality of metal structures spanning a second interface portion between the first semiconductor structure and the second semiconductor structure;
wherein the second plurality of metal structures are disposed in at least one second high-K dielectric layer; and
wherein the second plurality of metal structures and the at least one second high-K dielectric layer comprise at least one other capacitor.

22. The apparatus of claim 21, wherein the at least one capacitor and the at least one other capacitor are connected to each other in parallel.

23. A method, comprising:
forming a first semiconductor structure on a first semiconductor substrate, wherein the first semiconductor structure comprises a first plurality of metal pads disposed in a first high-K dielectric layer;
forming a second semiconductor structure on a second semiconductor substrate, wherein the second semiconductor structure comprises a second plurality of metal pads disposed in a second high-K dielectric layer;
aligning respective ones of the first plurality of metal pads with respective ones of the second plurality of metal pads; and
performing a thermal treatment process to bond the first semiconductor structure to the second semiconductor structure, wherein the thermal treatment process integrates the first plurality of metal pads with the second plurality of metal pads to create a plurality of metal structures spanning an interface between the first semiconductor structure to the second semiconductor structure;
wherein the plurality of metal structures and the first and second high-K dielectric layers form at least one capacitor.

24. The method of claim 23, wherein a material of the first high-K dielectric layer is different from a material of the second high-K dielectric layer.

25. The method of claim 23, wherein the thermal treatment process anneals the first plurality of metal pads and the second plurality of metal pads.
